(19) United States
(12) Patent Application Publication
(10) Pub. No.: US 2015/0033772 A1
(43) Pub. Date: Feb. 5, 2015

(54) APPARATUS AND METHOD FOR COOLING ELECTRIC COMPONENTS

(71) Applicant: ABB RESEARCH LTD, Zurich (CH)

(72) Inventors: Bruno AGOSTINI, Zurich (CH); Mathieu Habert, Rheinfelden (CH); Francesco Agostini, Zofingen (CH); Thomas Paul, Wadenswil (CH)

(73) Assignee: ABB Research Ltd., Zurich (CH)

(21) Appl. No.: 14/450,917

(22) Filed: Aug. 4, 2014

(30) Foreign Application Priority Data
Aug. 2, 2013 (EP) 13179085.9

(51) Int. Cl. H05K 7/20; F25B 27/02

(52) U.S. Cl. CPC H05K 7/20363; F25B 27/02; H05K 7/20309; H05K 7/20318
USPC 62/79; 62/238.3

(57) ABSTRACT

An apparatus is disclosed which includes a generator receiving a heat load from first electric components, an evaporator for receiving a heat load from second electric components, a tight enclosure, and an absorber-condenser arranged outside of the tight enclosure. For efficient cooling of the apparatus, one or more of the generator, evaporator and absorber-condenser is entirely or partly manufactured of aluminum. The inert and refrigerant can be selected such that R134a is used as the inert and butane as the refrigerant fluid, or R32 is used as the inert and cyclopropane is used as the refrigerant, and the absorber is selected to include an alkyl acetamide, a carbonate ester or a glycol ester.

### RELATED APPLICATION

This application claims priority under 35 U.S.C. §119 to European Patent Application No. 13179085.9 filed in Europe on Aug. 2, 2013, the entire content of which is hereby incorporated by reference in its entirety.

### FIELD

This present disclosure relates to a solution for cooling electric components of an electric apparatus.

### BACKGROUND INFORMATION

Known refrigeration systems are dual pressure cycles where the saturation temperature difference between a condenser and an evaporator is produced by a system pressure difference. This involves a mechanical input to drive the compressor or pump for generating the change in pressure.

Such systems use a mechanical input to drive a compressor or pump.

Other known solutions utilize a generator, an evaporator and an absorber-condenser manufactured of steel, and circulate three different working fluids without the need for a mechanical input, compressor or pump. These known solutions are low efficiency and can have high manufacturing costs.

### SUMMARY

An apparatus is disclosed, comprising: a generator; an evaporator; and an absorber-condenser for circulating an absorber, an inert fluid and a refrigerant, wherein: the generator is configured to receive a heat load from first electric components, the generator including a fluid channel for receiving fluid including a mixture of the absorber and the inert fluid, and being configured to evaporate a part of the received fluid with the heat load from the first electric components; the evaporator is configured to receive a heat load from second electric components, the evaporator including a fluid channel for a fluid mixture of the inert fluid and the refrigerant for transferring heat received from the second electric components into the fluid mixture of the fluid channel; the absorber-condenser is configured to receive heated absorber from the generator and heated inert fluid and refrigerant from the evaporator, and to transfer heat from the received fluids to surroundings; and one or more of the generator, evaporator and absorber-condenser is entirely or partly manufactured of aluminum.

A method is disclosed for selecting a combination of three different working fluids including an absorber, an inert fluid and a refrigerant for a cooling system, comprising: selecting the inert fluid and refrigerant such that R134a is used as the inert fluid and butane as the refrigerant fluid, or R32 is used as the inert fluid and cyclopropane is used as the refrigerant; and selecting the absorber to include an alkyl acetamide, a carbonate ester or a glycol ester.

### BRIEF DESCRIPTION OF DRAWINGS

In the following, disclosed features and advantages will be described in closer detail by way of example and with reference to the attached drawings, in which:

FIGS. 1 to 7 illustrate an exemplary embodiment of an apparatus as disclosed herein; and

FIG. 8 illustrates an exemplary operation of an apparatus.

### DETAILED DESCRIPTION

An apparatus is disclosed which can provide more efficient cooling of electric components, and a method is disclosed for selecting working fluids for a cooling system.

In the following discussion, a absorber fluid is designated by the letter A, a refrigerant by the letter R, and an inert fluid (or pressure equalizing fluid) by the letter I. The “liquid state” is designated by the letter 1 and the “gas state” by the letter g (it is to be understood that “gas” is used to distinguish from liquid state and includes vapor state, (e.g., a liquid that has just undergone phase change). Thus, for example A-l designates liquid absorber and (R+I)-g a mixture of refrigerant and inert fluids in the gas state. Practically all the flows in the apparatus can be mixtures of two fluids with low or high concentrations, but to simplify the description, only high concentration mixtures are explicitly mentioned as such. Thus it is to be understood that A-l is a liquid absorbant which may have a low concentration of inert absorbed, while (A+I)-l is a liquid absorbant which may have a high concentration of inert absorbed.

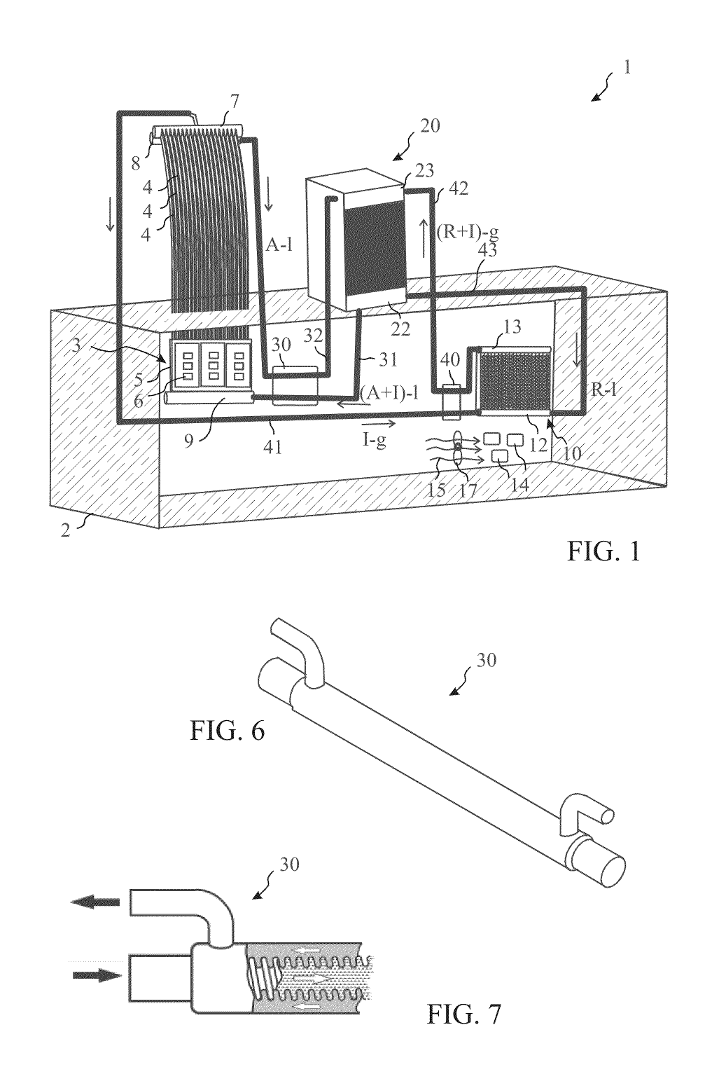

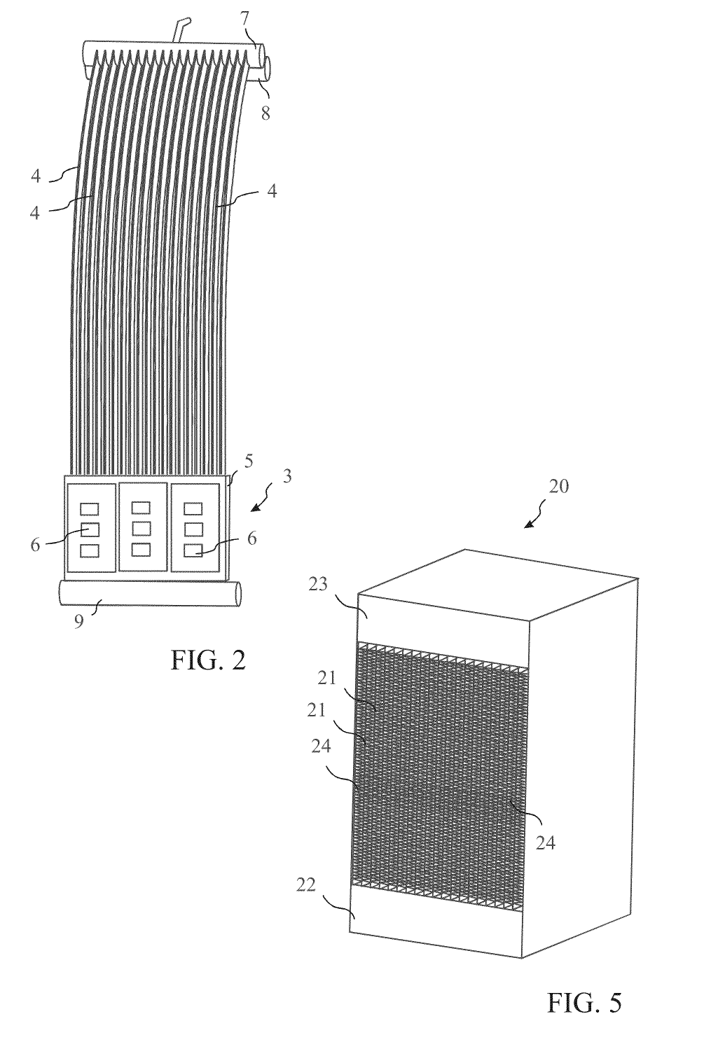

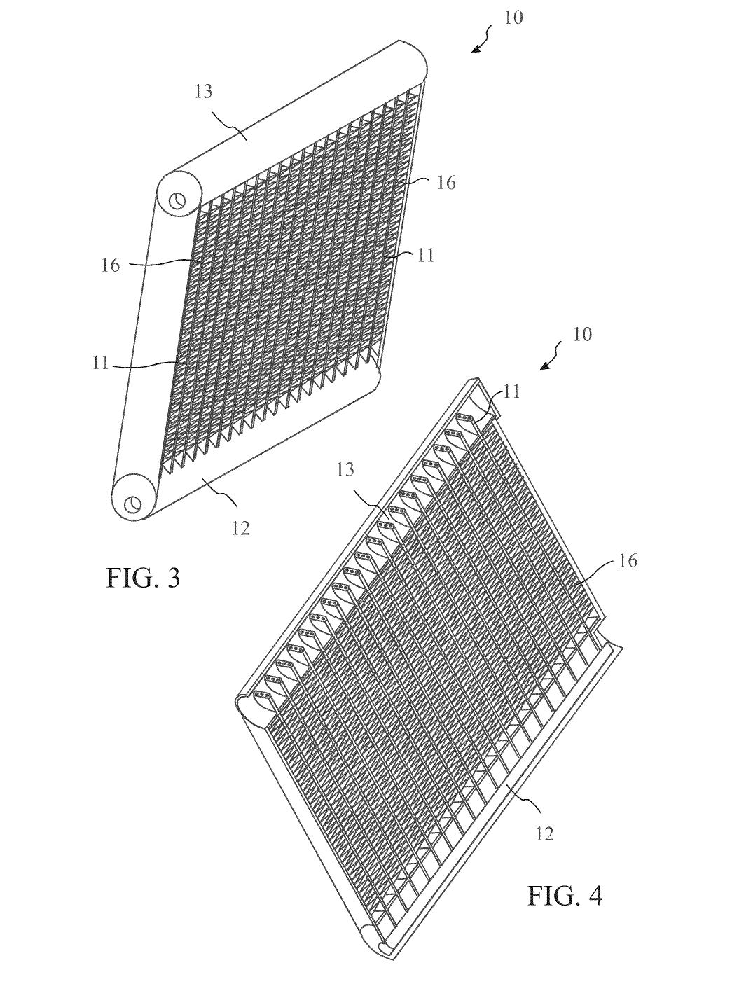

FIGS. 1 to 7 illustrate an exemplary embodiment of an apparatus 1. FIG. 1 is a front view of the apparatus, FIG. 2 illustrates details of an exemplary generator, FIGS. 3 and 4 details of an exemplary evaporator, FIG. 5 details of an exemplary absorber-condenser and FIGS. 6 and 7 of an exemplary solution heat exchanger.

The apparatus 1 includes a tight enclosure 2 enclosing electric devices, such as an electrical cabinet or a component space. Tight refers in this context to an enclosure 2 which, for example, restricts air from flowing between the inside and outside of the enclosure, though in practical implementations some leakage may occur. The electric components within this hermetic enclosure 2 can be cooled as explained below. It should, however, be observed that a tight enclosure is not necessary in all embodiments. One alternative instead of having a tight enclosure is, for instance, to have two separate airflows that do not mix together. The first air flow may pass heat towards the evaporator, for instance, while the other separate airflow passes heat away from the condenser-absorber, for instance.

A cooling element referred to as a generator 3 is arranged with a lower part within the enclosure 2 and with an upper part outside of the enclosure. The generator 3 includes a plurality of tubes 4 which are divided by longitudinal internal walls into a plurality of channels. One alternative is to manufacture the tubes of the generator of multiport extruded tubes (MPE tubes). Such tubes may be manufactured by extruding aluminum, for instance.

The generator 3, which is illustrated in more detail in FIG. 2, is at its lower end provided with a baseplate 5. Such a baseplate 5 may be manufactured of aluminum, for instance. Electric components 6 which during use produce large amounts of heat are attached to the baseplate 5 and thermally connected to the baseplate 5 for conducting heat from the electric components 6 via the baseplate 5 to fluid in the tubes 4. The electric components 6 may be high power electronic components of a motor drive used for supplying an electric motor with electricity, for instance.

The baseplate 5 is provided with parallel grooves into which the tubes 4 partly penetrate. Some of the longitudinal channels of the MPE tubes are therefore embedded into the baseplate 5.

At the upper end of the generator 3, the tubes 4 are connected to a first manifold 7. This manifold may be implemented as a tube providing a fluid path between each of the channels in the tubes 4. A reservoir 8 is provided as a second tube, which is in fluid communication with the manifold 7 and located lower than the manifold 7. Thereby liquid and gas exiting the channels of the tubes 4 at the upper ends of the tubes are separated by gravity. The liquid flows downwards by gravity and accumulates into the reservoir 8 while the gas remains in manifold 7.

From FIGS. 1 and 2 one can observe that the exemplary tubes 4 can be curved. The reason for this curvature is to promote and/or ensure that the liquid will accumulate into the liquid reservoir 8 by gravity. Therefore this generator 3 manufactured of curved multiport extruded tubes in FIGS. 1 and 2 can fulfill three different functions:

A vapour generator: gas is generated inside the section of the tubes 4 that penetrate into the baseplate 5 due to the heat dissipated by the electric components 6, such as power modules.

A bubble pump: The internal longitudinal channels of the tubes 4 are capillary sized channels. In this context “capillary sized” refers, for example, to channels that have a size small enough for bubbles to grow uniquely in a longitudinal direction (in other words in the longitudinal direction of the channel as opposed to the radial direction) and thereby create a so called bubble lift effect by pushing the liquid upwards. The diameter of a channel or tube which is considered capillary depends on the fluid or refrigerant that is used (boiling) inside. The following formula, for instance, can be used to evaluate a suitable diameter: D=(sigma/(g*(rhol−rhov)))̂0.5 (i.e., D=(σ/g*(ρ1−ρv)))^{0.5}, wherein sigma is the surface tension, g the acceleration of gravity, rhov the gas density and rhol the liquid density. For example, the internal diameter of such capillary channels is around 1.5 mm. Therefore bubbles will grow along the channels direction towards the lowest pressure point only and therefore push liquid up to the top of the tubes 4 into the manifold 7.

A separator reservoir: the manifold 7 and the reservoir 8 can have one or more fluid connections and therefore act as a vapour-liquid separator and reservoir due to gravity and the mutual location of the manifold and reservoir.

The apparatus 1 of FIG. 1 can also include an evaporator 10, an example of which is illustrated in more detail in FIGS. 3 and 4. The evaporator 10 is composed of an air heat exchanger with tubes 11 attached to a bottom manifold 12 (implemented as a tube) and a top manifold 13 (implemented as a tube).

In the illustrated example the tubes 11 are MPE tubes with longitudinal intermediate walls that divide the tubes into a plurality of channels. Air fins 16 can be brazed between the parallel tubes 11.

An inert gas I-g is injected into a liquid refrigerant R-l with a diffuser tube inserted into the bottom manifold 12, for instance. The evaporated mixture of refrigerant and inert is collected into the top manifold 13. The evaporator 10 can be made of MPE tubes, but this is not necessary.

The evaporator 10 provides cooling to secondary electric components 14 arranged inside the tight enclosure 2. These secondary electric components 14 can be thermally connected to the evaporator 10. One alternative is that the thermal connection is obtained by an air stream 15 passing via the electric components 14 to the fins 16 of the evaporator 10, such that the fins 16 conduct heat from the air stream 15 to fluid in the tubes 11. In order to provide an efficient air circulation within the enclosure 2, a fan 17 generating the air stream 15 may be utilized. The electric components 14 may be capacitors and PCBs (Printed Circuit Board) which during use can, for example, generate a relatively low amount of heat, but which use an efficient cooling in order to avoid problems due to a temperature raise. For example, the power of the second components 14 may be 5 to 10 times lower than the power of the electric components 6 components.

The apparatus 1 of FIG. 1 can include an exemplary absorber-condenser 20 shown in more detail in FIG. 5. The absorber-condenser 20 can be installed outside of the tight enclosure 2. The illustrated exemplary absorber-condenser 20 is composed of an air heat exchanger with tubes 21 attached to a bottom manifold 22, which may be implemented as a tube, and a top manifold 23, which also may be implemented as a tube. In order to enhance transfer of heat between the absorber-condenser 20 and the surrounding air, fins 24 can be arranged between the tubes 21 by brazing, for instance. Additionally, a second fan (not illustrated) may be arranged outside of the enclosure 2 to generate an airflow passing between the tubes 21 of the absorber-condenser 20.

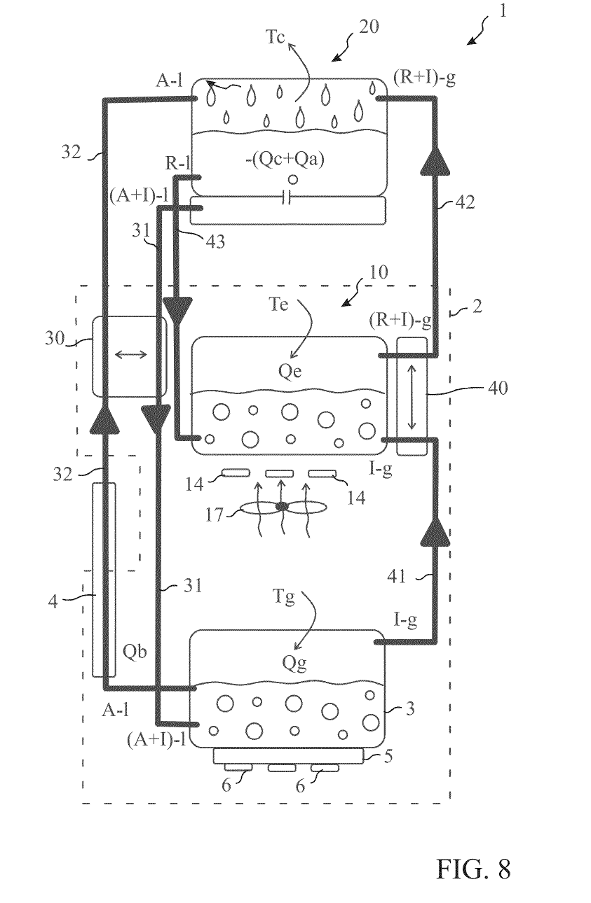

The absorber-condenser 20 may be manufactured of aluminum, for instance, by a plate and bar heat exchanger technology, for instance. The absorber-condenser 20 can, for example, respect the following constraints:
a) the flow length of the channels provided by the tubes 21, and therefore the height of the absorber-condenser, should be high enough to allow complete absorption of the inert gas I-g into the absorber in a liquid state A-l and of the refrigerant received in a gas state R-g in to a liquid state R-l. This height can be determined with classical heat and mass transfer correlations.
b) the cold weak absorber in a liquid state A-1 coming from the solution heat exchanger 30 is allowed to shower evenly the refrigerant+inert gas mixture (R+l)-g entering the top manifold 23. Therefore the top manifold 23 may be designed for this purpose, with a porous plate inserted in the middle for example.
c) during the absorption and condensation processes, which can take place together, the different fluids can have a contact area as large as possible. Therefore the diameter of the fluid channels provided by the tubes 21 is large enough to avoid the formation of gas plugs and liquid plugs (for example, a few times the capillary dimension) because these would keep the gas and liquid spatially separated and hinder the absorption process.
d) the liquid pure refrigerant R-l and the liquid strong solution of absorbant+inert (A+I)-l can be harvested in the bottom manifold 22. As these two fluids are immiscible and of different densities, they will separate naturally by gravity (illustrated in FIG. 8). The size and design of the bottom manifold 22 allows this natural separation to occur. Alternatively a commercial liquid-liquid separator (not illustrated in the Figures) may be installed below the bottom manifold 22.

The apparatus of FIG. 1 can also include a solution heat exchanger 30 that can be a standard commercial tube-in-tube heat exchanger as shown in more detail in FIGS. 6 and 7, and where the liquid strong absorber line 31 (containing the mixture of absorber and inert in a liquid state (A+I)-l) pre-cools the liquid weak absorber line 32 (containing the absorber in a liquid state A-l). It should be observed that in FIG. 1 the solution heat exchanger 30 representation is simplified and shown as two tubes 31 and 32 running side by side. Although this configuration would allow heat exchange, the tube-in-tube commercial solution can be much more efficient because it has a larger heat transfer area.

The apparatus of FIG. 1 also includes an exemplary gas heat exchanger 40 that can be a standard commercial tube-in-tube heat exchanger, similar as the solution heat exchanger 30 illustrated in FIGS. 6 and 7.

It should be observed that in FIG. 1 heat transfer occurs, for example, only between the line 41 with inert fluid in the gas state I-g and the line 42 with a mixture of refrigerant and inert fluid (R+I)-g, both in a gas state. However, as an alternative it is possible to have line 42 with a mixture of refrigerant and inert fluid (R+I)-g to pre-cool both line 41 with inert fluid in a gas state I-g and line 43 with the refrigerant in a liquid state R-1 before they enter the evaporator 10. This can be achieved by, for example, installing two tube-in-tube heat exchangers 40 in series, for instance.

A line 41 with inert fluid in a gas state I-g extends from the top manifold 7 of the generator 3 to the bottom manifold 12 of the evaporator 10 through the gas heat exchanger 40. A line 32 with the liquid weak absorber A-1 extends from the liquid reservoir 8 of the generator 3 to the top manifold 23 of the absorber-condenser 20 through the solution heat exchanger 30. A line 31 with a liquid strong absorber (A+I)-l extends from the bottom manifold of the absorber-condenser 22 to the bottom manifold 9 of the generator 3 through the solution heat exchanger 30.

The line 43 with the liquid refrigerant R-1 can extend from the bottom manifold 22 of the absorber-condenser 20 to the bottom manifold 12 of the evaporator 10 and optionally through the gas heat exchanger 40. Line 43 should, for example, exit from the manifold 22 of the absorber-condenser 20 above the level of liquid strong solution of absorbant+inert (A+I)-l exiting via line 31(as shown in FIG. 8). In this way an adequate separation can be obtained due to gravity.

A line 42 with a gas refrigerant+inert mixture in a gas state (R+I)-g extends from the top manifold 13 of the evaporator 10 to the top manifold 23 of the absorber-condenser 23 through the gas heat exchanger 40.

As most clearly illustrated in FIG. 1, the tubes 4, which may be MPE tubes of aluminum, for instance, extend out of the enclosure to a higher altitude than the top of the absorber-condense 20. This can promote and/or ensure efficient circulation within the apparatus.

FIG. 8 illustrates exemplary operation of the apparatus. The apparatus illustrated in FIGS. 1 to 7 may, for example, operate as explained in the following.

Three different fluids are circulated in the apparatus 1: an absorber A, a refrigerant R and an inert fluid I (which also is called a pressure equalizing gas). The absorber A and inert fluid I should, for example, have a large boiling temperature difference to allow a good separation of the absorber A and inert fluid I fluid in the generator. The saturation temperature of the refrigerant R at the system pressure should be greater than the saturation temperature of the inert I at the system pressure. The inert fluid I should, for example, be strongly absorbed by the absorber A at the system pressure and at the saturation temperature of the refrigerant R. The refrigerant R should, for example, be of limited immiscibility (e.g., be nearly immiscible 10% or less) with the absorber A and inert I fluid mixture. The three fluids may not chemically react with each other or with other materials present in the apparatus, which may be manufactured of aluminum, for instance. The absorber A fluid should have a high saturation temperature at the system pressure. Ideally, for example, the refrigerant R and inert I mixture should be able to form an azeotrope in the evaporator temperature so that there is no temperature glide during the evaporation, which would improve the coefficient of performance.

The exemplary apparatus illustrated in FIG. 8 has six heat exchangers circulating three fluids, as explained above. The terms “weak” and “strong” are used to refer to the amount of inert gas in the mixture.

A pre-heated strong liquid solution of inert and absorber (A+I)-l enters the generator 3 from the solution heat exchanger 30 via line 31. This liquid solution is vaporized by the heat load Qg from the electric components 6 and produces a strong gas mixture of inert I-g and absorber and a weak liquid solution of inert and absorber A-l.

The upper end of the generator 3, which may be provided with tubes 4 (having capillary dimensions) partly extending out of the enclosure 2 (as illustrated in FIG. 1) works as a bubble pump starting from the generator tank (bottom manifold 9 of the generator 3). The bubble pump 4 sends the absorber in a liquid state A-l to the solution heat exchanger 30 via line 32, due to the growth of spatially confined bubbles created in the bubble pump due to the capillary size of the pipes 4 and the heat load Qb. The solution heat exchanger 30 pre-cools the weak liquid solution of the absorber A-l sent by the bubble pump with the strong liquid solution of inert and absorber (A+I)-l coming out of the absorber-condenser 20 via line 31. This pre-cooling increases the capacity of the absorber liquid A-l to absorb more inert I-g in the absorber-condenser 20 and therefore can improve the effectiveness of the cycle. Optionally the weak solution A-l can be further pre-cooled with the outside air before it enters the absorber-condenser 20.

The inert gas line 41 passes the strong gas mixture of the inert gas I-g to the gas heat exchanger 40 from the generator 3. The gas heat exchanger 40 precools the inert gas I-g (which at this point ideally includes (e.g., consists to) 100% of inert gas, but in practice may contain some absorber gas) with the strong inert and refrigerant gas mixture (R+I)-g coming out from the evaporator 10. Due to this pre-cooling refrigeration may occur in the evaporator.

The absorber-condenser 20, which is located outside of the enclosure 2, can have a double function: firstly it receives the pre-heated strong inert and refrigerant gas mixture (R+I)-g coming out from the gas heat exchanger 40 via line 42 and showers it with the pre-cooled weak absorber liquid A-l coming out from the solution heat exchanger 30 in order to absorb the inert gas I-g into the absorber A-l, thus forming a strong liquid solution of inert (A+I)-l at the exit of the absorber-condenser 20 (line 31). Secondly it condenses the refrigerant into liquid R-l above atmospheric air temperature, which is possible since the partial pressure of the refrigerant without the inert is high. Then the two non-miscible liquids R-l and (A+I)-l are separated at the bottom manifold 22 of the absorber-condenser 20 by gravity. Both the absorption and condensation are exothermic phenomena and reject a total heat load (Qc+Qa) into the surroundings outside of the enclosure 2. Qa is the absorption heat and Qc is the condensation heat.

The evaporator 10 receives liquid refrigerant R-l from the absorber-condenser 20 via line 43. The liquid refrigerant may optionally (not illustrated in the drawings) be precooled in a gas heat exchanger. Additionally, the evaporator 10 receives via line 41 pre-cooled strong gas mixture of inert I-g from the generator 3 via the gas heat exchanger 40. The inert in the gas state I-g reduces a partial pressure of the liquid refrigerant R-l and therefore also the temperature required for evaporating the liquid refrigerant R-l. The relatively low heat load Qe from the electric components 14 attached to the evaporator 10 or arranged inside the enclosure where they are thermally connected to the evaporator via air (and possibly a fan 17 generating an airflow), can therefore be sufficient in the presence of inert gas I-g to evaporate the liquid refrigerant R-l. Evaporation can therefore be achieved a relatively low temperature Te. This phenomena is endothermic and absorbs a heat load Qe from inside of the tight enclosure 2.

Attention should be paid to the selection of the fluids utilized in the apparatus. In order to be able to utilize heat exchangers manufactured of materials that efficiently conduct heat, suitable fluids should be selected. For example, it is possible to utilize aluminum in the heat exchangers, as aluminum has good heat conducting properties (as compared to steel for instance) and as heat exchangers of aluminum are relatively easy to manufacture by extrusion and/or a combination of extrusion and soldering, for instance. Furthermore they can be compact and low cost.

An exemplary process for selecting fluid combinations to be used in the previously described apparatus may be as follows:
1) Choose a refrigerant+inert combination and a working pressure so that:
   i) at 100% refrigerant the condensation temperature will be significantly higher than the cooling air temperature (e.g., at least 10 K higher).
   ii) a certain concentration of refrigerant mixed with inert gas exists so that this mixture will evaporate at a significantly lower temperature than that of the enclosure to be cooled (e.g., at least 10 K lower). This concentration should be ideally, for example, around 50% to minimize flow rates. However it can vary from, for example, 10% to 90%.
   iii) the difference between the condensation and the evaporation temperature is called the temperature lift and indicates how much below ambient you can hope to refrigerate the enclosure containing the electronic equipment.
2) Choose an absorber fluid so that at the working pressure determined by the refrigerant+inert combination and at the absorption temperature (that is equal to the condensation temperature since the two phenomena take place in the same heat exchanger), the concentration of inert gas in the absorber is as high as possible. This can ensure that the generator exit temperature is as low as possible (and therefore the semiconductor operating temperature is low) and that the concentration of absorber in the vaporized inert gas is as low as possible (which can improve the coefficient of performance since this absorber gas does not play any refrigeration role in the evaporator).

For the exemplary described apparatus utilizing aluminum in the heat exchangers excellent fluid combinations may be achieved with the following exemplary fluid combinations:
as the inert fluid R134a (1,1,1,2-Tetrafluoroethane) in combination with butane
as the refrigerant fluid, or
as the inert fluid R32 (Difluoromethane) in combination with cyclopropane as the refrigerant fluid.

With the above two exemplary alternatives, possible exemplary absorbers are:
alkyl acetamides, linear and cyclic, such as DMEU (Dimethylol-ethylene-urea) or DMAC (Dimethylacetamide)
carbonate esters, such as DMC (Dimethyl carbonate)
glycol ethers, such as DMEDEG (Dimethylether diethylene glycol), DMETEG (DiMethyl Ether Tetra Ethylene Glycol), DMETrEG (Dimethylether Triethylene Glycol).

The use of a novel combination of inert fluid, refrigerant and absorber as working fluids in the apparatus makes it possible to manufacture the components of the apparatus of a material which is very well suitable for use in a cooling device, in other words aluminum. This also simplifies the manufacturing of the apparatus.

It is to be understood that the above description and the accompanying figures are only intended to illustrate exemplary features of present invention. It will be apparent to those skilled in the art that embodiments can be varied and modified without departing from the scope of the invention.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

1. An apparatus comprising:
a generator;
an evaporator; and
an absorber-condenser for circulating an absorber, an inert fluid and a refrigerant, wherein:
the generator is configured to receive a heat load from first electric components, the generator including a fluid channel for receiving fluid including a mixture of the absorber and the inert fluid, and being configured to evaporate a part of the received fluid with the heat load from the first electric components;
the evaporator is configured to receive a heat load from second electric components, the evaporator including a fluid channel for a fluid mixture of the inert fluid and the refrigerant for transferring heat received from the second electric components into the fluid mixture of the fluid channel;
the absorber-condenser is configured to receive heated absorber from the generator and heated inert fluid and refrigerant from the evaporator, and to transfer heat from the received fluids to surroundings; and
one or more of the generator, evaporator and absorber-condenser is entirely or partly manufactured of aluminum.

2. The apparatus according to claim 1, comprising:
an enclosure for enclosing the generator and the evaporator, the absorber-condenser being arranged outside of the enclosure for transferring heat to outside of the enclosure.

3. The apparatus according to claim 1, wherein the inert fluid and refrigerant are selected such that R134a is used as the inert fluid and butane as the refrigerant fluid, or R32 is used as the inert fluid and cyclopropane is used as the refrigerant; and
the absorber is selected to include an alkyl acetamide, a carbonate ester or a glycol ester.

4. The apparatus according to claim 1, wherein the fluid channel of the evaporator is configured to receive the refrigerant in a liquid state and the inert fluid in a gas state, whereby the inert fluid in the gas state reduces a partial pressure of the refrigerant in a liquid state and a temperature required for evaporating the refrigerant in the liquid state, such that the refrigerant in the liquid state is evaporated.

5. The apparatus according to claim 1, in combination with first and second electric components, wherein an operating temperature of the second electric components is lower than an operating temperature of the first electric components.

6. The apparatus according to claim 1, in combination with first and second electric components, wherein the first electric components include high power electronic devices, and the second electric components include passive electric components.

7. The apparatus according to claim 1, wherein:
the fluid channel of the generator is arranged to heat received fluids with heat received from first electric components, to provide the absorber-condenser with the absorber in a liquid state, and to provide the fluid channel of the evaporator with the vaporized inert fluid in a gas state;
the fluid channel of the evaporator is arranged to receive the vaporized inert fluid in a gas state from the generator and to receive the refrigerant in a liquid state, to heat the received fluids with heat from second electric components and to provide the absorber-condenser with the vaporized inert fluid and vaporized refrigerant as a gas mixture; and
the absorber-condenser is arranged to receive the absorber in a liquid state from the generator and the vaporized inert fluid and vaporized refrigerant as a gas mixture from the evaporator, to absorb the vaporized inert fluid by the absorber in a liquid state in order to obtain a liquid of miscible inert fluid and absorber and to condense the refrigerant, which is of limited miscibility or not miscible with the absorber and inert fluid, into a liquid state while transferring heat from the fluids to a surrounding, and to provide the generator with the absorber and inert fluid as a liquid mixture and the evaporator with the refrigerant in a liquid state.

8. The apparatus according to claim 1, wherein the generator comprises:
a bubble pump as tubes which have capillary dimensions and partly extend out of an enclosure enclosing the generator and the evaporator, to a higher altitude than an upper part of the absorber-condenser which is located outside of the enclosure, for providing the absorber-condenser with the absorber in a liquid state.

9. The apparatus according to claim 8, wherein the tubes are curved multiport extruded tubes that are divided by internal longitudinal walls into a plurality of channels, the channels of the multiport extruded tubes comprising:
a manifold in an upper end of the tubes, said manifold being in a fluid connection with the evaporator for providing the evaporator with inert fluid in a gas state; and
a reservoir which is located lower than the manifold for receiving and providing the absorber-condenser with absorber in a liquid state.

10. The apparatus according to claim 7, comprising:
a solution heat exchanger for cooling the absorber provided in a liquid state from the generator to the absorber-condenser with the absorber and inert fluid as a liquid mixture provided by the absorber-condenser to the generator.

11. The apparatus according to claim 7, comprising:
a gas heat exchanger for transferring heat between the inert fluid provided in the gas state from the generator to the evaporator and the vaporized inert fluid and refrigerant in the gas mixture provided by the evaporator to the absorber-condenser.

12. A method for selecting a combination of three different working fluids including an absorber, an inert fluid and a refrigerant for a cooling system, comprising:
selecting the inert fluid and refrigerant such that R134a is used as the inert fluid and butane as the refrigerant fluid, or R32 is used as the inert fluid and cyclopropane is used as the refrigerant; and
selecting the absorber to include an alkyl acetamide, a carbonate ester or a glycol ester.

13. The apparatus according to claim 8, comprising:
a solution heat exchanger for cooling the absorber provided in a liquid state from the generator to the absorber-condenser, with the absorber and inert fluid as a liquid mixture being provided by the absorber-condenser to the generator.

14. The apparatus according to claim 8, comprising:
a gas heat exchanger for transferring heat between the inert fluid provided in the gas state from the generator to the evaporator, the vaporized inert fluid and refrigerant in the gas mixture being provided by the evaporator to the absorber-condenser.
